(19) United States
(12) Patent Application Publication
(10) Pub. No.: US 2026/0271361 A1
(43) Pub. Date: Sep. 10, 2026

(54) METHOD OF FABRICATING SEMICONDUCTOR DEVICE

(71) Applicant: Taiwan Semiconductor Manufacturing Company, Ltd., Hsinchu (TW)

(72) Inventors: Yuan Tsung Tsai, Tainan City (TW); Ying Ming Wang, Tainan City (TW); Wei Shun Huang, Tainan City (TW); Hsien-Chung Huang, Hsinchu (TW); Wei Che Tsai, Pingtung City (TW); Sung-Hsin Yang, Tainan City (TW)

(73) Assignee: Taiwan Semiconductor Manufacturing Company, Ltd., Hsinchu (TW)

(21) Appl. No.: 19/075,691

(22) Filed: Mar. 10, 2025

(51) Int. Cl. H10D 64/01; H01L 21/3115; H10D 30/01; H10D 30/62; H10D 30/69; H10D 62/13; H10D 64/66

(52) U.S. Cl. CPC H10D 64/021; H10D 30/024; H10D 30/797; H10D 64/017; H10D 64/675; H10P 30/40; H10D 30/6211; H10D 62/151

(57) ABSTRACT

A method of fabricating a semiconductor device includes the following steps. A substrate is patterned to form a plurality of active regions. Isolation features are formed alongside the active regions. Dummy gate structures are formed on the active regions and formed on spacer films aside the dummy gate structures. A doping process is performed on the spacer films to reduce a coefficient of thermal expansion (CTE) value of the spacer films. An interlayer dielectric layer is formed on the isolation features and aside the spacer films. The dummy gate structures are replaced with gate structures.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (e.g., the number of interconnected devices per chip area) has generally increased while geometry size (e.g., the smallest component (or line) that can be created using a fabrication process) has decreased. This scaling down process generally provides benefits by increasing production efficiency and lowering associated costs. However, scaling down has also led to challenges that may not have been presented by previous generations at larger geometries.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is an exemplary flow chart showing the process steps of a method of fabricating a semiconductor device in accordance with some embodiments of the present disclosure.

FIG. 2 to FIG. 12C are the perspective views and cross-sectional views illustrating various stages of a method of fabricating semiconductor devices in accordance with some embodiments of the present disclosure.

FIG. 13A and FIG. 13B are perspective and cross-sectional views illustrating a semiconductor device in accordance with some other embodiments of the disclosure.

FIG. 14 and FIG. 15 are perspective views illustrating various stages of a method of fabricating semiconductor devices in accordance with some comparative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

The embodiments of the present disclosure describe the exemplary manufacturing processes of a three-dimensional structure with height differences and the structure(s) fabricated there-from. Certain embodiments of the present disclosure describe the exemplary manufacturing processes of fin field-effect transistor (FinFET) devices and the FinFET devices fabricated there-from. The FinFET device may be formed on a monocrystalline semiconductor substrate, such as a bulk silicon substrate in certain embodiments of the present disclosure. In some embodiments, the FinFET device may be formed on a silicon-on-insulator (SOI) substrate or a GOI (germanium-on-insulator) substrate as alternatives. Also, in accordance with the embodiments, the silicon substrate may include other conductive layers, doped regions or other semiconductor elements, such as transistors, diodes or the like. The embodiments are intended to provide further explanations but are not used to limit the scope of the present disclosure.

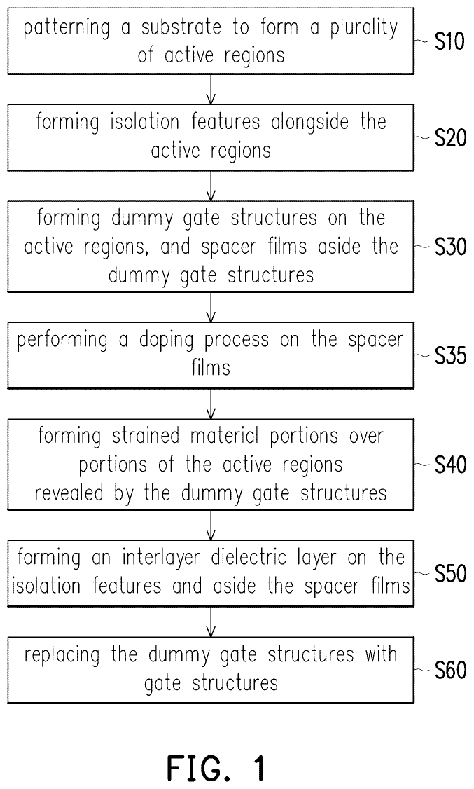

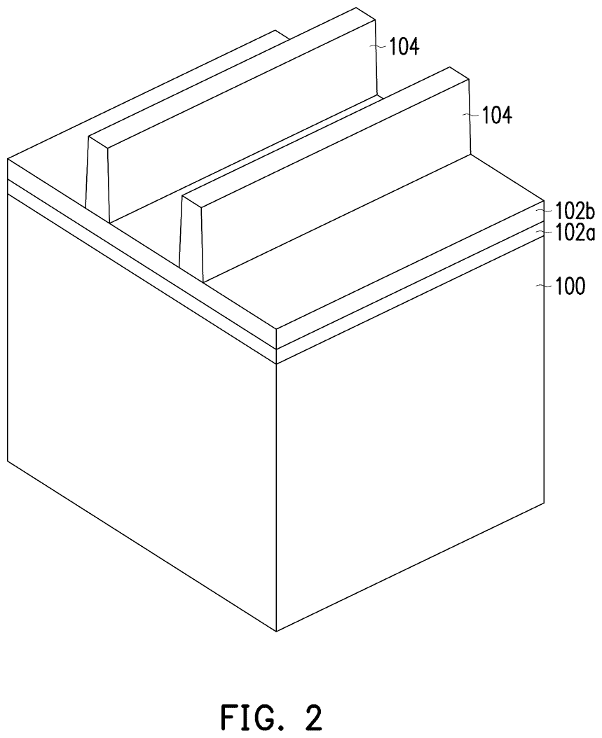

FIG. 1 is an exemplary flow chart showing the process steps of a method of fabricating a semiconductor device in accordance with some embodiments of the present disclosure. The various process steps of the process flow illustrated in FIG. 1 may comprise multiple process steps as discussed below. FIG. 2 to FIG. 12C are the perspective views and cross-sectional views illustrating various stages of a method of fabricating semiconductor devices in accordance with some embodiments of the present disclosure. It is to be noted that the process steps described herein cover a portion of the manufacturing processes used to fabricate a semiconductor device, such as a FinFET device.

FIG. 2 is a perspective view of the semiconductor device at one of various stages of the manufacturing method. In step S10 in FIG. 1 and as shown in FIG. 2, a substrate 100 is provided. The substrate 100 may be a semiconductor substrate. In one embodiment, the substrate 100 comprises a crystalline silicon substrate (e.g., wafer). The substrate 100 may comprise various doped regions depending on design requirements (e.g., p-type semiconductor substrate or n-type semiconductor substrate). In some embodiments, the doped regions may be doped with p-type or n-type dopants. For example, the doped regions may be doped with p-type dopants, such as boron or BF₂; n-type dopants, such as phosphorus or arsenic; and/or combinations thereof. The doped regions may be configured for an n-type FinFET, or alternatively configured for a p-type FinFET. In some alternative embodiments, the substrate 100 may be made of some other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide.

In one embodiment, a pad layer 102a and a mask layer 102b are sequentially formed on the semiconductor substrate 100. The pad layer 102a may be a silicon oxide thin film formed, for example, by thermal oxidation process. The pad layer 102a may act as an adhesion layer between the substrate 100 and the mask layer 102b. The pad layer 102a may also act as an etch stop layer for etching the mask layer 102b. In at least one embodiment, the mask layer 102b is a silicon nitride layer formed, for example, by low-pressure chemical vapor deposition (LPCVD) or plasma enhanced chemical vapor deposition (PECVD). The mask layer 102b is used as a hard mask during subsequent photolithography processes. In certain embodiments, a patterned photoresist layer 104 having a predetermined pattern is formed on the mask layer 102b.

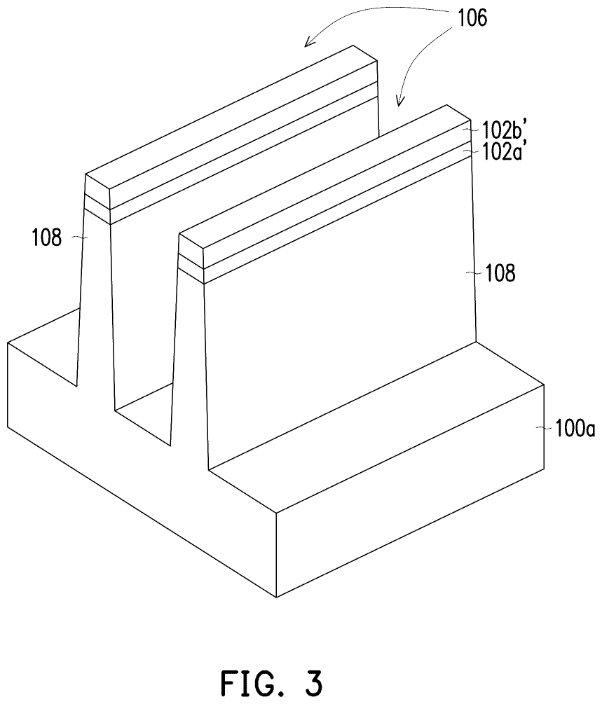

FIG. 3 is a perspective view of the semiconductor device at one of various stages of the manufacturing method. In step S10 in FIG. 1 and as shown in FIG. 3, the substrate 100 is patterned to form trenches 106 in the substrate 100 and a plurality of semiconductor strips 108 (or active regions) are formed between the trenches 106. For example, the mask layer 102b and the pad layer 102a which are not covered by the patterned photoresist layer 104 are sequentially etched to form a patterned mask layer 102b′ and a patterned pad layer 102a′ so as to expose the underlying substrate 100. By using the patterned mask layer 102b′, the patterned pad layer 102a′ and the patterned photoresist layer 104 as a mask, portions of the substrate 100 are exposed and etched to form the trenches 106 and the semiconductor strips 108 (or active regions). In some embodiments, the semiconductor strips 108 includes a plurality of semiconductor fins. In some embodiments, the semiconductor strips 108 are covered by the patterned mask layer 102b′, the patterned pad layer 102a′ and the patterned photoresist layer 104. Two adjacent trenches 106 are spaced apart by a spacing. For example, the spacing between trenches 106 may be smaller than about 30 nm. In other words, two adjacent trenches 106 are spaced apart by a corresponding semiconductor strip 108. The number of the semiconductor strips 108 (or active regions) shown in FIG. 3 is merely for illustration, in some alternative embodiments, two or more parallel semiconductor strips 108 (or active regions) may be formed in accordance with actual design requirements.

In some embodiments, a height of the semiconductor strips 108 (or active regions) and the depth of the trench 106 range from about 5 nm to about 500 nm. After the trenches 106 and the semiconductor strips 108 (or active regions) are formed, the patterned photoresist layer 104 is then removed. In one embodiment, a cleaning process may be performed to remove a native oxide of the patterned substrate 100a and the semiconductor strips 108 (or active regions). The cleaning process may be performed using diluted hydrofluoric (DHF) acid or other suitable cleaning solutions.

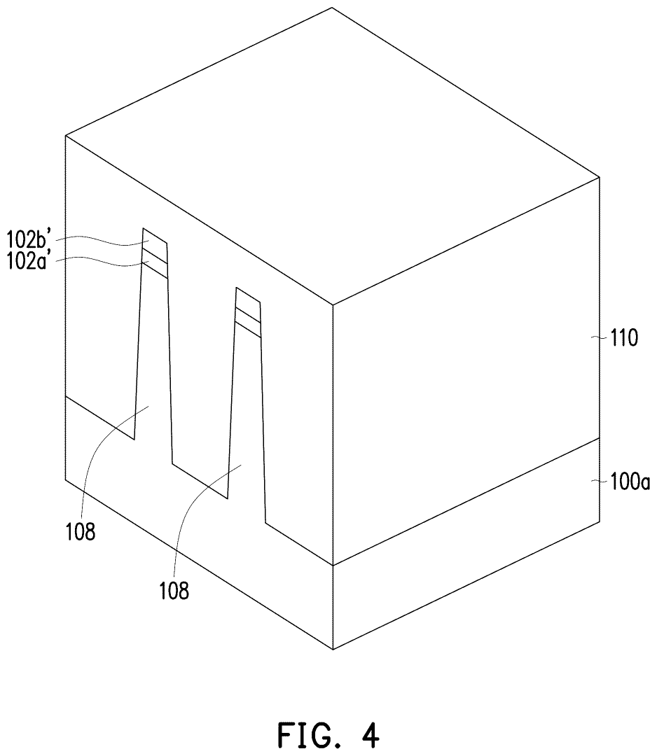

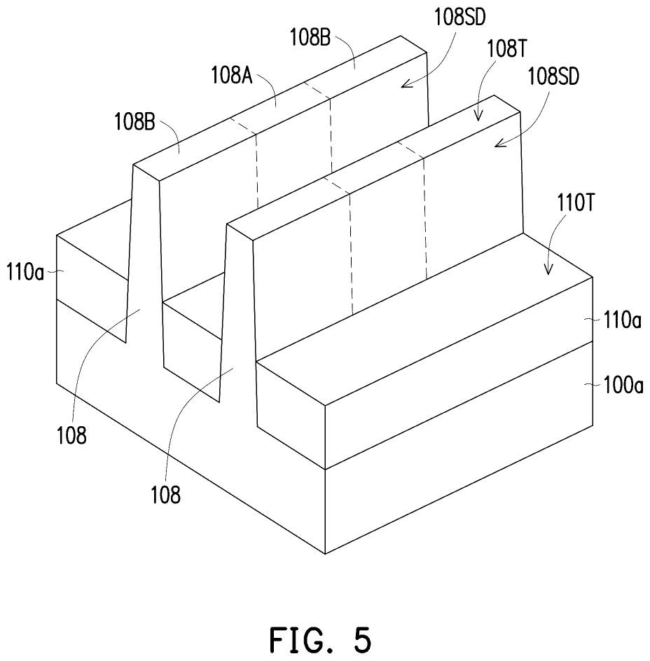

FIG. 4 and FIG. 5 are perspective views of the semiconductor device at one of various stages of the manufacturing method. In step S20 in FIG. 1 and as shown in FIG. 4 to FIG. 5, a plurality of isolation features 110a is formed in the trenches 106 of the substrate 100a. As illustrated in FIG. 4, in some embodiments, an insulating material 110 is first formed over the substrate 100a to cover the semiconductor strips 108 and to fill up the trenches 106. Besides covering the semiconductor strips 108, the insulating material 110 is also covering the patterned pad layer 102a′ and the patterned mask layer 102b′. In some embodiments, the insulating material 110 may include silicon oxide, silicon nitride, silicon oxynitride, a spin-on dielectric material, or a low-K dielectric material. It should be noted that the low-K dielectric materials are generally dielectric materials having a dielectric constant lower than 3.9. The insulating material 110 may be formed by high-density-plasma chemical vapor deposition (HDP-CVD), sub-atmospheric chemical vapor deposition (SACVD) or by spin-on processes.

Referring to FIG. 5, after forming the insulating material 110, etching processes are performed to remove a portion of the insulating material 110, the patterned mask layer 102b′ and the patterned pad layer 102a′ until the semiconductor strips 108 (or active regions) are exposed. In some embodiments, the insulating material 110 filled in the trenches 106 is partially removed by the etching process such that the isolation features 110a are formed on the substrate 100a and located aside the semiconductor strips 108. For example, each isolation feature 110a is located between two adjacent semiconductor strips 108 (or active regions). In one embodiment, the etching process may be a wet etching process with hydrofluoric acid (HF) or a dry etching process. In some embodiments, the top surfaces 110T of the isolation features 110a are lower than the top surfaces 108T of the semiconductor strips 108 (or active regions), so that sidewalls 108SD of the semiconductor strips 108 are partially exposed. The semiconductor strips 108 (or active regions) protrude from the top surfaces 110T of the isolation features 110a. The height difference between the top surfaces 108T of the semiconductor strips 108 and the top surfaces 110T of the isolation features 110a ranges from about 15 nm to about 50 nm. In some embodiments, the protruded portions of the semiconductor strips 108 include a channel region 108A and source/drain regions 108B located aside the channel region 108A. In certain embodiments, the source/drain regions 108B of the semiconductor strips 108 are of substantially the same height as that of the channel region 108A of the semiconductor strips 108.

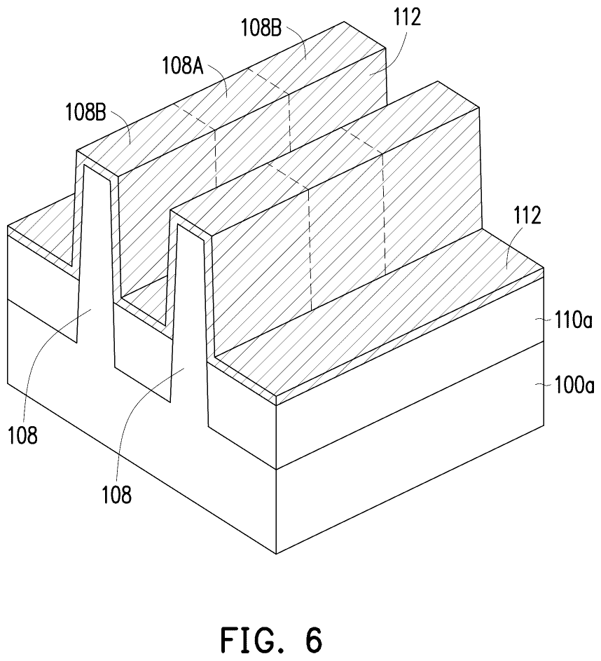

FIG. 6 is a perspective view of the semiconductor device at one of various stages of the manufacturing method. After the step S20 in FIG. 1 and as shown in FIG. 6, a dielectric layer 112 is formed to conformally cover the top surfaces 110T of the isolation features 110a, the top surfaces 108T of the semiconductor strips 108, and sidewalls 108SD of the semiconductor strips 108. In some embodiments, the material of the dielectric layer 112 may be silicon oxide, silicon nitride, silicon carbonitride or the like. In some embodiments, the dielectric layer 112 may be formed by a suitable process such as atomic layer deposition (ALD), chemical vapor deposition (CVD), physical vapor deposition (PVD), thermal oxidation or UV-ozone oxidation. In some alternative embodiments, the formation of a dielectric layer 112 on the isolation features 110a may be omitted.

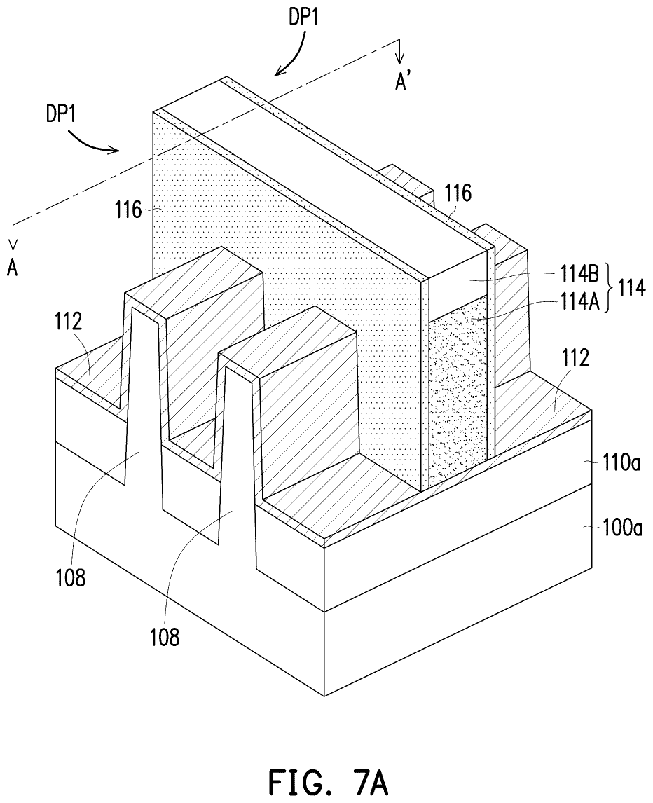

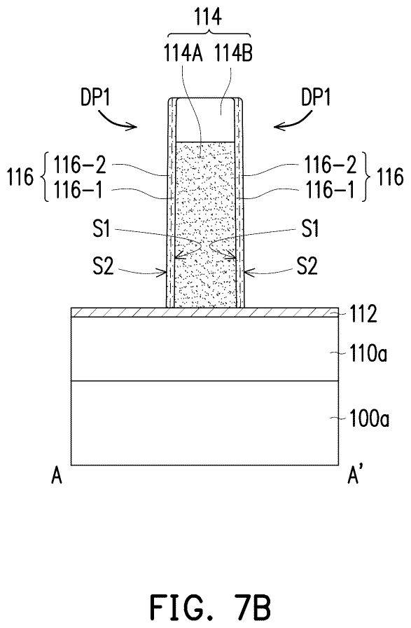

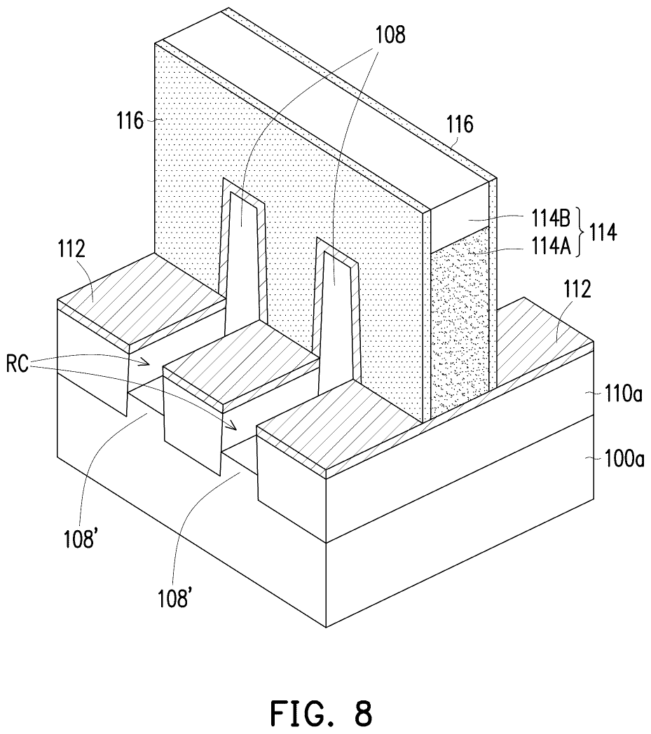

FIG. 7A is a perspective view of the semiconductor device at one of various stages of the manufacturing method. FIG. 7B is a sectional view illustrating the semiconductor device of FIG. 7A taken along the line A-A′. In step S30 in FIG. 1 and as shown in FIG. 7A and FIG. 7B, a dummy gate structure 114 is formed on the dielectric layer 112 and on the semiconductor strips 108 (or active regions). The dummy gate structure 114 may include a polysilicon strip 114A and a hard mask strip 114B. In some embodiments, the dummy gate structure 114 is formed by forming a dummy layer (including a polysilicon layer and a hard mask layer) over the dielectric layer 112 and across the semiconductor strips 108, and patterning the dummy layer to form the polysilicon strip 114A and the hard mask strip 114B. In the exemplary embodiment, although one dummy gate structure 114 is illustrated herein, it should be noted that the number of dummy gate structure 114 is not limited to one and may be more than one. In some embodiments, the extension direction of the dummy gate structure 114 (the polysilicon strip 114A and the hard mask strip 114B) is arranged to be perpendicular to the extension direction of the semiconductor strips 108 (or active regions), and the dummy gate structure 114 is arranged across the semiconductor strips 108 and covers the channel region 108A of the semiconductor strips 108. In one embodiment, the material of the hard mask strip 114B includes silicon nitride, silicon oxide or the combination thereof.

Referring still to FIG. 7A and FIG. 7B, after forming the dummy gate structure 114, spacer films 116 are formed on two opposite sides of the dummy gate structure 114. In some embodiments, the spacer films 116 are located on the dielectric layer 112 and are covering sidewalls of the polysilicon strip 114A and the hard mask strip 114B. In some embodiments, the spacer films 116 may be formed by conformally forming a spacer material layer over the dielectric layer 112 and over the dummy gate structure 114, then performing an etching process on the spacer material layer to form the spacer films 116. In some embodiments, the spacer films 116 are formed of one or more dielectric materials, such as silicon nitride, silicon carbon oxynitride (SiCON), silicon carbonitride (SiCN) or combinations thereof. The spacer films 116 may be a single layer or a multilayered structure. In some embodiments, the spacer films 116 is formed by depositing a blanket layer of one or more dielectric materials. In one embodiment, the spacer films 116 has a thickness ranging from 3 nm to 10 nm.

In the exemplary embodiment, in the step S35 in FIG. 1 and as shown in FIG. 7A and FIG. 7B, a doping process DP1 is performed on the spacer films 116. For example, the doping process DP1 may be performed on the spacer material layer prior to the etching process to form the spacer films 116, or may be performed after the etching process and on the spacer films 116. In some embodiments, the doping process DP1 includes performing ion implantation with at least one ion implant selected from argon (Ar), xenon (Xe), antimony (Sb), indium (In) and arsenic (As). In other words, the spacer films 116 are doped with a dopant, and the dopant is at least one selected from argon (Ar), xenon (Xe), antimony (Sb), indium (In) and arsenic (As). In some embodiments, a dose concentration of the ion implant in the ion implantation process is in a range of 2*1014 atoms/cm² to 10¹⁸ atoms/cm². In some embodiments, the doping process DP1 includes performing ion implantation with multiple ion implants, such as two ion implants. In such embodiment, a first ion implant is argon (Ar), and a second ion implant is any one of xenon (Xe), antimony (Sb), indium (In) and arsenic (As). In certain embodiments, the dielectric layer 112 located underneath the spacer films 116 may be partially doped during the doping process DP1 with the same dopants.

In some embodiments, a depth of the implanted elements (dopants) may be adjusted so that the concentration of ions implanted into the spacer films 116 are varied in different regions of the spacer films 116. For example, as shown in FIG. 7A and FIG. 7B, each of the spacer films 116 have a first surface S1 facing the dummy gate structures 114, and a second surface S2 opposite to the first surface S1 and facing away from the dummy gate structures 114. In some embodiments, a concentration of ions implanted into the spacer films 116 adjacent to the first surface S1 is lower than a concentration of the ions implanted into the spacer films 116 adjacent to the second surface S2.

In some embodiments, the spacer films 116 are formed with a first portion 116-1 and a second portion 116-2. The first portion 116-1 is contacting the dummy gate structure 114 and includes the first surface S1, and the second portion 116-2 is connected to first portion 116-1 and includes the second surface S2. In the exemplary embodiment, a concentration of ions implanted into the second portion 116-2 of the spacer films 116 is higher than a concentration of ions implanted into the first portion 116-1 of the spacer films 116 during the doping process DP1. In other words, the second portion 116-2 has a higher dopant concentration than the first portion 116-1 in the spacer films 116. However, the disclosure is not limited thereto, and in some alternative embodiments, a concentration of the dopant in the first portion 116-1 varies from a concentration of the dopant in the second portion 116-2. For example, the dopant concentration in the first portion 116-1 and the second portion 116-2 may be adjusted based on design requirements.

In the exemplary embodiment, the doping process DP1 is performed to reduce a coefficient of thermal expansion (CTE) value of the spacer films 116 (including the first portion 116-1 and the second portion 116-2). For example, in one embodiment, if the spacer films 116 are made of silicon nitride having a CTE value of 2.3 ppm/K, then the spacer films 116 are doped through the doping process DP1 to reduce the CTE value to less than 2.3 ppm/K. In some embodiments, the spacer films 116 have tensile stress before performing the doping process DP1, and have compressive stress after performing the doping process DP1.

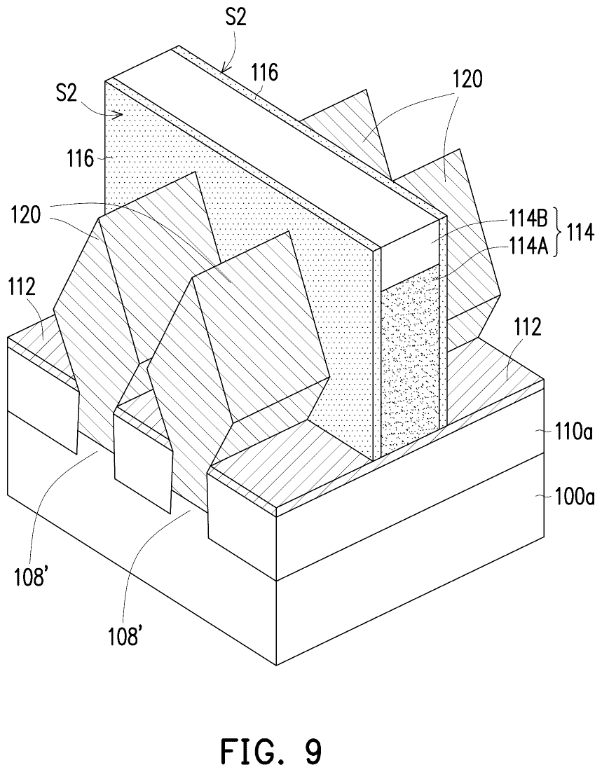

FIG. 8 and FIG. 9 are perspective views of the semiconductor device at one of various stages of the manufacturing method. In step S40 in FIG. 1 and as shown in FIG. 8 to FIG. 9, strained material portions 120 are formed over the semiconductor strips 108. For example, as shown in FIG. 8, portions of the semiconductor strips 108 (or active regions) in the source/drain regions 108B are removed to form recesses RC. For example, portions of the semiconductor strips 108 may be removed by, anisotropic etching, isotropic etching, or a combination thereof. In some embodiments, portions of the semiconductor strips 108 are recessed below the top surfaces 110T of the isolation features 110a to form recessed portions 108'. In some embodiments, a depth of the recesses RC is less than a thickness of the isolation features 110a. In other words, the semiconductor strips 108 exposed by the dummy gate structure 114 and the spacer films 116 are not entirely removed, and the remaining semiconductor strips 108 (the recessed portions 108') located in the recesses RC form the source/drain regions of the semiconductor strips 108.

Referring to FIG. 9, in a subsequent step, strained material portions 120 are formed in the recesses RC, and formed over the recessed portions 108′ of the semiconductor strips 108. In some embodiments, the strained material portions 120 extends beyond the top surfaces of the isolation features 110a, and extend beyond the top surface of the dielectric layer 112. In some embodiments, the strained material portions 120 covers and contacts the recessed portions 108′ of the semiconductor strips 108. In some embodiments, the strained material portions 120 are located on two opposite sides of the dummy gate structure 114.

In the exemplary embodiment, the strained material portions 120 (or a high doped low resistance material) is grown on the source/drain regions 108B of the semiconductor strips 108 to strain or stress the semiconductor strips 108. Thus, the strained material portions 120 comprises a source disposed at a side of the dummy gate structure 114 and a drain disposed at the other side of the dummy gate structure 114. The source covers an end of the semiconductor strips 108 and the drain covers the other end of the semiconductor strips 108. In some embodiments, the strained material portions 120 may be doped with a conductive dopant. In one embodiment, the strained material portions 120 include materials such as SiGe, and is epitaxial-grown with a p-type dopant for straining a p-type FinFET. That is, the strained material portions 120 is doped with the p-type dopant to be the source and the drain of the p-type FinFET. The p-type dopant comprises boron or BF₂, and the strained material portions 120 may be epitaxial-grown by LPCVD process with in-situ doping. In another embodiment, the strained material portions 120 include materials such as SiC, SiP, a combination of SiC/SiP, or SiCP, and is epitaxial-grown with an n-type dopant for straining an n-type FinFET. That is, the strained material portions 120 is doped with the n-type dopant to be the source and the drain of the n-type FinFET. The n-type dopant comprises arsenic and/or phosphorus, and the strained material portions 120 may be epitaxial-grown by LPCVD process with in-situ doping. The strained material portions 120 may be a single layer or a multi-layer.

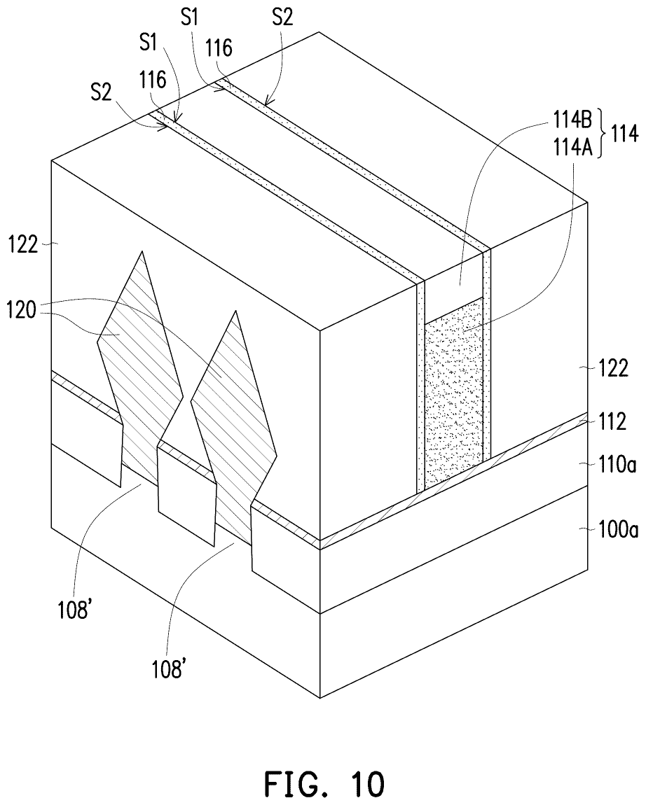

FIG. 10 is a perspective view of the semiconductor device at one of various stages of the manufacturing method. In step S50 in FIG. 1 and as shown in FIG. 10, an interlayer dielectric layer 122 is formed on the isolation features 110a and aside the spacer films 116. In some embodiments, the interlayer dielectric layer 122 is formed on the isolation features 110a and covering the strained material portions 120. In some embodiments, the interlayer dielectric layer 122 includes silicon oxide, silicon nitride, silicon oxynitride, phosphosilicate glass (PSG), borophosphosilicate glass (BPSG), spin-on glass (SOG), fluorinated silica glass (FSG), carbon doped silicon oxide (e.g., SiCOH), polyimide, and/or a combination thereof. In some other embodiments, the interlayer dielectric layer 122 includes low-K dielectric materials. Examples of low-K dielectric materials include BLACK DIAMOND® (Applied Materials of Santa Clara, Calif.), Xerogel, Aerogel, amorphous fluorinated carbon, Parylene, BCB (bis-benzocyclobutenes), Flare, SILK® (Dow Chemical, Midland, Mich.), hydrogen silsesquioxane (HSQ) or fluorinated silicon oxide (SiOF), and/or a combination thereof. It is understood that the interlayer dielectric layer 122 may include one or more dielectric materials and/or one or more dielectric layers.

In some embodiments, the interlayer dielectric layer 122 is formed to a suitable thickness by flowable CVD (FCVD), CVD, high density plasma CVD (HDPCVD), sub-atmospheric CVD (SACVD), spin-on, sputtering, or other suitable methods. Specifically, an interlayer dielectric material layer (not illustrated) is formed to cover the isolation features 110a and the dummy gate structure 114 first. Subsequently, the thickness of the interlayer dielectric material layer is reduced until a top surface of the dummy gate structure 114 is exposed, so as to form the interlayer dielectric layer 122. The process of reducing the thickness of the interlayer dielectric material layer is achieved by a chemical mechanical polishing (CMP) process, an etching process, or other suitable process. The disclosure is not limited thereto.

In some embodiments, an etch-stop layer or contact etch-stop layer (not shown) is formed on the isolation features 110a and aside the spacer films 116 prior to forming the interlayer dielectric layer 122. For example, the etch stop layer may be formed of silicon oxide, silicon nitride, silicon carbo-nitride, or the like. In some embodiments, the etch stop layer may be formed through, for example, CVD, SACVD, Molecular Layer Deposition (MLD), ALD, or the like. Subsequently, the interlayer dielectric layer 122 may be formed on the etch-stop layer.

As illustrated in FIG. 10, after forming the interlayer dielectric layer 122, the second surface S2 of the spacer films 116 is facing the interlayer dielectric layer 122. In other words, the second portion 116-2 of the spacer films 116 with higher dopant concentration is sandwiched in between the first portion 116-1 and the interlayer dielectric layer 122. In the exemplary embodiment, the spacer films 116 have a first CTE value prior to the doping process DP1 described in FIG. 7A and FIG. 7B, while the interlayer dielectric layer 122 has a second CTE value different from the first CTE value. For example, in one embodiment, the spacer films 116 are made of silicon nitride having a CTE value of 2.3 ppm/K, while the interlayer dielectric layer 122 is made of silicon oxide having a CTE value of 0.5 ppm/K. In the exemplary embodiment, after performing the doping process DP1 on the spacer films 116, the first CTE value of the spacer films is altered so that a CTE difference between the first CTE value of the spacer films 116 (doped) and the second CTE value of the interlayer dielectric layer 122 is reduced. As such, a CTE mismatch between the materials of the interlayer dielectric layer 122 and the spacer films 116 is minimized. Furthermore, a problem of gate width reduction caused by tensile stress of the spacer films 116 during subsequent thermal treatment process can be mitigated.

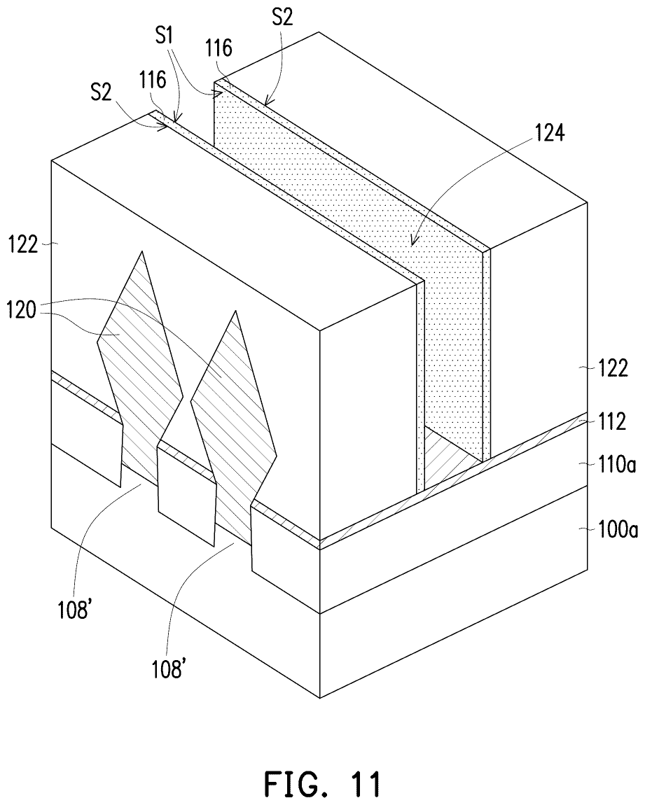

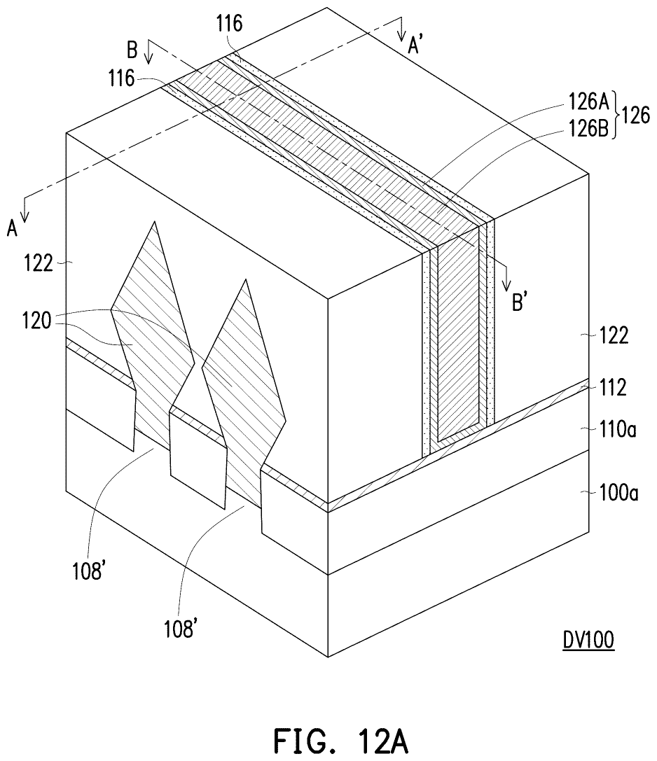

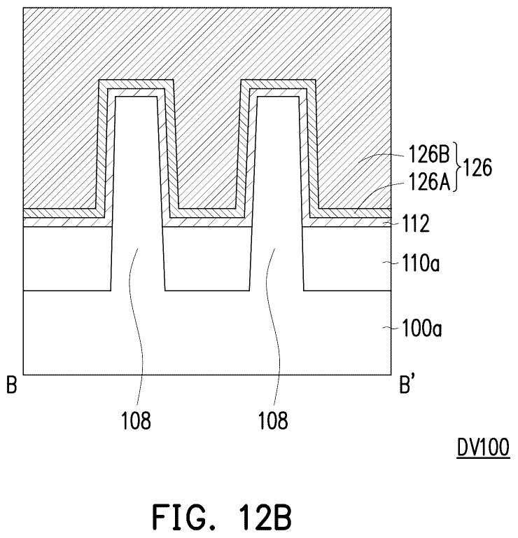

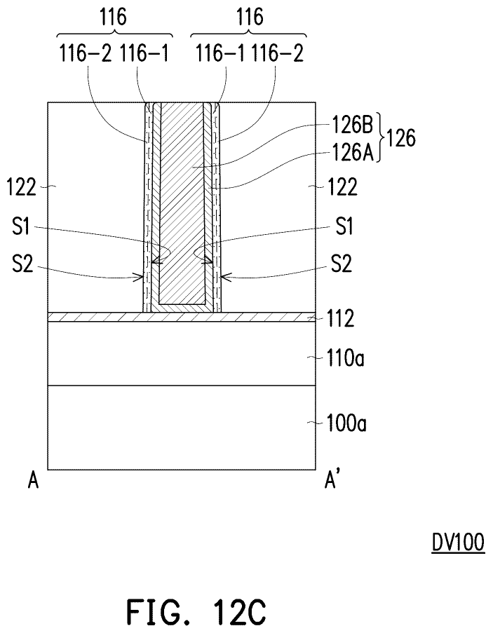

In the step S60 shown in FIG. 1, and referring to FIG. 11 to FIG. 12C, after forming the interlayer dielectric layer 122, the dummy gate structure 114 is then replaced with the gate structures 126. As illustrated in FIG. 11, the dummy gate structure 114 located on the channel region 108A of the semiconductor strips 108 is removed to form a trench 124. In some embodiments, the polysilicon strip 114A and the hard mask strip 114B located on the channel region 108A of the semiconductor strips 108 are removed. In one embodiment, the polysilicon strips 114A and the hard mask strips 114B are removed by anisotropic etching, whereas the spacer films 116 and the dielectric layer 112 are retained. In some embodiments, after removing the dummy gate structure 114, the first surface S1 of the spacer films 116 and the top surface of the dielectric layer 112 are exposed.

In some embodiments, after removing the dummy gate structure 114 as shown in FIG. 11, a thermal treatment process is performed. For example, the thermal treatment process is performed on the semiconductor strips 108, the spacer films 116 and the interlayer dielectric layer 122. In certain embodiments, the thermal treatment process is a thermal annealing process, which is performed at a temperature range of 600° C. to 1300° C. In the exemplary embodiment, since the spacer films 116 are doped with a dopant to reduce its CTE value, a deformation of the spacer films 116 caused by tensile stress during the thermal treatment process is avoided.

FIG. 12A is a perspective view of the semiconductor device at one of various stages of the manufacturing method. FIG. 12B is a sectional view illustrating the semiconductor device of FIG. 12A taken along the line B-B′. FIG. 12C is a sectional view illustrating the semiconductor device of FIG. 12A taken along the line A-A′. Referring to FIG. 12A to FIG. 12C, after removing the dummy gate structure 114, a gate structure 126 is formed over the channel region 108A of the semiconductor strips 108 within the trench 124 to replace the dummy gate structure 114.

As illustrated in FIG. 12A to FIG. 12C, the gate structure 126 includes a gate dielectric layer 126A and a gate electrode layer 126B, and the gate structure 126 is located in between the spacer structures 218. In an embodiment, the gate dielectric layer 126A is formed within the recesses between the spacer films 116 and on the dielectric layer 112, and over the channel regions 108A of the semiconductor strips 108. In some embodiments, the gate dielectric layer 126A is conformally formed on the dielectric layer 112 and over the semiconductor strips 108. In some embodiments, the gate dielectric layer 126A of the gate structure 126 is contacting the first surface S1 or the first portion 116-1 of the spacer films 116. In other words, the first portion 116-1 of the spacer films 116 having lower dopant concentration is adjacent to the gate structure 126, while the second portion 116-2 of the spacer films 116 having higher dopant concentration is adjacent to the interlayer dielectric layer 122.

In some embodiments, the material of the gate dielectric layer 126A includes silicon oxide, silicon nitride or the combination thereof. In some embodiments, the gate dielectric layer 126A includes a high-k dielectric material, and the high-k dielectric material has a k value greater than about 3.9 and includes a metal oxide or a silicate of Hf, Al, Zr, La, Mg, Ba, Ti, Pb and combinations thereof. In some embodiments, the gate dielectric layer 126A is formed by atomic layered deposition, molecular beam deposition (MBD), physical vapor deposition (PVD) or thermal oxidation. After forming the gate dielectric layer 126A, the gate electrode layer 126B is formed on the gate dielectric layer 126A, over the channel region 108A of the semiconductor strips 108 and fills the remaining recesses between the spacer films 116. In certain embodiments, the gate dielectric layer 126A is formed in between the gate electrode layer 126B and the dielectric layer 112.

In some embodiments, the gate electrode layer 126B includes a metal-containing material, such as Al, Cu, W, Co, Ti, Ta, Ru, TiN, TiAl, TiAlN, TaN, TaC, NiSi, CoSi or a combination thereof. Depending on whether the semiconductor device is a p-type FinFET or an n-type FinFET, the materials of the gate dielectric layer 126A and/or the gate electrode layer 126B are appropriately chosen. Optionally, a chemical mechanical polishing (CMP) process is performed to remove the excess portions of gate dielectric layer 126A and the gate electrode layer 126B. The spacer films 116 are located on sidewalls of the gate dielectric layer 126A and the gate electrode layer 126B. In other words, the dummy gate structure 114 is replaced, and the gate structure 126 is formed. In some embodiments described herein, the gate structure 126 is a replacement metal gate, but the structure(s) of the gate structure 126 or the fabrication processes thereof are not limited by these embodiments. In some other embodiments, conductive contacts (not shown) may be formed in subsequent steps, and these conductive contacts may be electrically connected to the strained material portions 120 (e.g. source/drain contacts), or electrically connected to the gate structure 126 (e.g. gate contacts). Up to here, a semiconductor device DV100 according to some embodiments of the present disclosure is accomplished.

In the semiconductor device DV100, since the spacer films 116 are doped with a dopant having the designated concentration, a CTE mismatch between the materials of the interlayer dielectric layer 122 and the spacer films 116 is minimized. As such, a problem of gate width reduction of the gate structure 126 caused by tensile stress of the spacer films 116 during subsequent thermal treatment process can be mitigated. Overall, a stress in different areas of the semiconductor device DV100 can be adjusted to meet different electrical requirements.

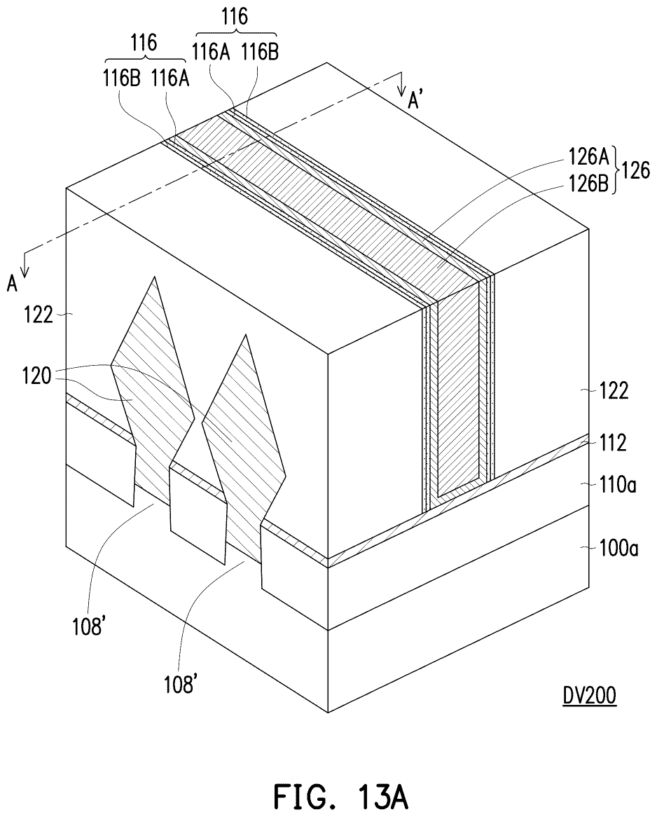

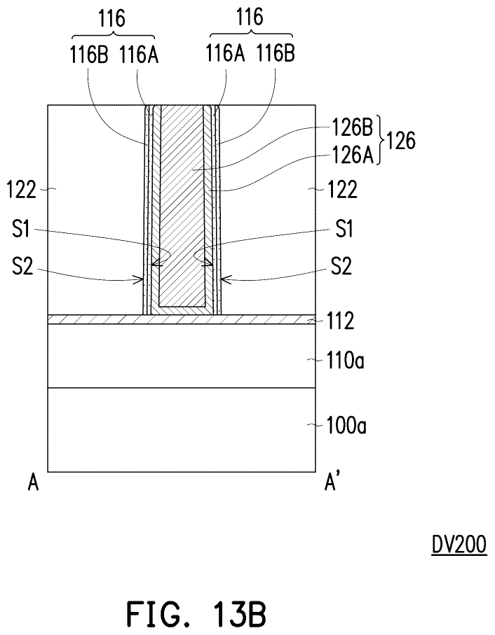

FIG. 13A and FIG. 13B are perspective and cross-sectional views illustrating a semiconductor device in accordance with some other embodiments of the disclosure. The semiconductor device DV200 shown in FIG. 13A and FIG. 13B is similar to the semiconductor device DV100 shown in FIG. 12A to FIG. 12C. Therefore, the same reference numerals are used to refer to the same or liked parts, and its detailed description will be omitted herein. In the embodiment shown in FIG. 12A to FIG. 12C, the spacer films 116 are a single material film that includes two portions (116-1, 116-2) with different dopant concentrations. However, the disclosure is not limited thereto. Referring to FIG. 13A and FIG. 13B, in some embodiments, each of the spacer films 116 are formed of a multilayered structure, wherein the multilayered structure includes a first layer 116A including the first portion 116-1 and a second layer 116B including the second portion 116-2.

In the exemplary embodiment, an interface exists between the first layer 116A and the second layer 116B of the spacer films 116. Furthermore, the first layer 116A and the second layer 116B are formed of dielectric materials, such as silicon nitride, silicon carbon oxynitride (SiCON), silicon carbonitride (SiCN) or combinations thereof. In one embodiment, the first layer 116A and the second layer 116B are made of different materials. In an alternative embodiment, the first layer 116A and the second layer 116B are made of the same material.

In some embodiments, a concentration of ions implanted into the first layer 116A of the spacer films 116 adjacent to the first surface S1 is lower than a concentration of the ions implanted into the second layer 116B of the spacer films 116 adjacent to the second surface S2 during the doping process. However, the disclosure is not limited thereto, and in some other embodiments, a concentration of ions implanted into the first layer 116A of the spacer films 116 is approximately the same as a concentration of the ions implanted into the second layer 116B. For example, the dopant concentration in the first layer 116A (or first portion 116-1) and the second layer 116B (or second portion 116-2) of the spacer films 116 may be adjusted based on design requirements. The first layer 116A and the second layer 116B may be doped by the same doping process DP1 as described in FIG. 7A and FIG. 7B, thus the details of the doping process will not be repeated herein.

In the semiconductor device DV200, since the spacer films 116 are doped with a dopant having the designated concentration, a CTE mismatch between the materials of the interlayer dielectric layer 122 and the spacer films 116 is minimized. As such, a problem of gate width reduction of the gate structure 126 caused by tensile stress of the spacer films 116 during subsequent thermal treatment process can be mitigated. Overall, a stress in different areas of the semiconductor device DV200 can be adjusted to meet different electrical requirements.

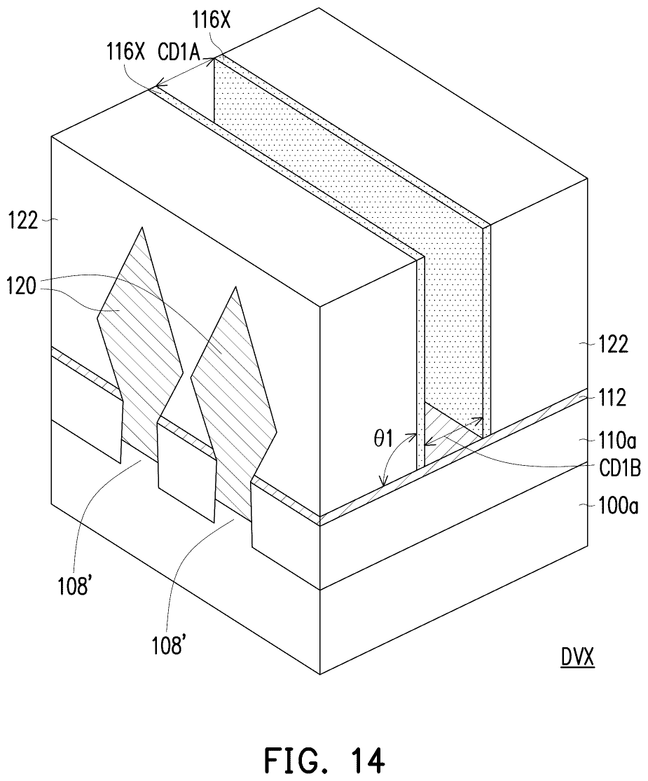

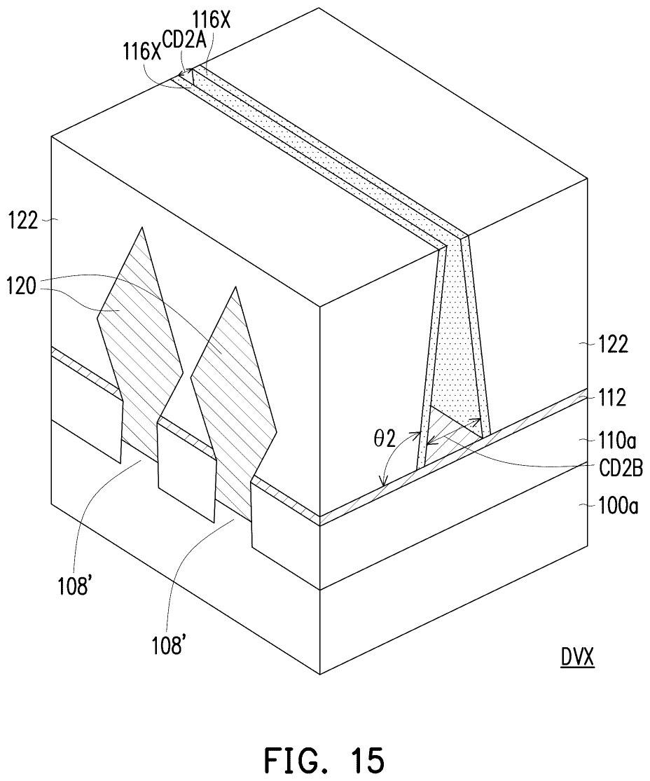

FIG. 14 and FIG. 15 are perspective views illustrating various stages of a method of fabricating semiconductor devices in accordance with some comparative embodiments of the present disclosure. The semiconductor device DVX illustrated in FIG. 14 and FIG. 115 is similar to the semiconductor device DV100 shown in FIG. 12A to FIG. 12C. Therefore, the same reference numerals are used to refer to the same or liked parts, and its detailed description will be omitted herein. The difference between the embodiments, is that the spacer films 116X of the semiconductor device DVX shown in FIG. 14 and FIG. 15 are undoped. For example, the spacer films 116X are made of the same materials as the spacer films 116, but without performing the doping process DP1.

In the comparative embodiment, as shown in FIG. 14, the same steps as described in FIG. 1 to FIG. 11 may be performed to form the semiconductor device DVX, except that the doping process DP1 described in FIG. 7A and FIG. 7B is not performed. As illustrated in FIG. 14, after removing the dummy gate structure 114, the semiconductor device DVX has a top gate width of CD1A and a bottom gate width of CD1B. The top gate width CD1A and the bottom gate width CD1B corresponds to a distance between top and bottom portions of two adjacent spacer films 116X. In some embodiments, a ratio (CD1A/CD1B) of the top gate width of CD1A to the bottom gate width CD1B is in a range of 0.95 to 1.05. In certain embodiments, the top gate width of CD1A is substantially equal to the bottom gate width CD1B. Furthermore, an angle θ1 of the spacer films 116X relative to the dielectric layer 112 is in a range of 88° to 92°. In certain embodiments, the angle θ1 of the spacer films 116X relative to the dielectric layer 112 is approximately 90°.

Referring to FIG. 15, in subsequent steps, a thermal treatment process may be performed. For example, the thermal treatment process is a thermal annealing process, which is performed at a temperature range of 600° C. to 1300° C. In the comparative embodiment, as the spacer films 116X are undoped, the spacer films 116X having tensile stress will deform during the thermal treatment process. For example, due to the deformation of the spacer films 116X caused by CTE mismatch, the top gate width CD1A shrinks after the thermal treatment process, and is reduced to form a top gate width of CD2A. In some embodiments, the bottom gate width CD1B is also slightly reduced to from a bottom gate width of CD2B. In the exemplary embodiment, a ratio (CD2A/CD2B) of the top gate width of CD2A to the bottom gate width CD2B is in a range of 0.5 to 0.9. In some embodiments, the ratio (CD2A/CD2B) of the top gate width of CD2A to the bottom gate width CD2B is in a range of 0.6 to 0.8. In other words, there is a substantial decrease in the distance between the top portion of the two adjacent spacer films 116X. Furthermore, an angle θ2 of the spacer films 116X relative to the dielectric layer 112 after the thermal treatment process is in a range of 93° to 110°. In certain embodiments, the angle θ2 of the spacer films 116X relative to the dielectric layer 112 is in a range of 95° to 100°. As such, when forming gate structures 126 in a subsequent step, a gate width of the gate structures 126 is limited by the reduced top gate width CD2A and the bottom gate width CD2B, which may degrade the performance of the semiconductor device DVX.

In the above-mentioned embodiments, in the fabricated semiconductor device, since the spacer films are doped with a dopant having the designated concentration, a CTE mismatch between the materials of the interlayer dielectric layer and the spacer films is minimized. As such, a problem of gate width reduction of the gate structure caused by tensile stress of the spacer films during subsequent thermal treatment process can be mitigated. Overall, a stress in different areas of the semiconductor device can be adjusted to meet different electrical requirements.

In accordance with some embodiments of the present disclosure, a method of fabricating a semiconductor device includes the following steps. A substrate is patterned to form a plurality of active regions. Isolation features are formed alongside the active regions. Dummy gate structures are formed on the active regions and formed on spacer films aside the dummy gate structures. A doping process is performed on the spacer films to reduce a coefficient of thermal expansion (CTE) value of the spacer films. An interlayer dielectric layer is formed on the isolation features and aside the spacer films. The dummy gate structures are replaced with gate structures.

In accordance with some other embodiments of the present disclosure, a method of fabricating a semiconductor device includes the following steps. A plurality of semiconductor strips is formed on a substrate. Spacer films are formed on the semiconductor strips, and a doping process is performed on the spacer films. An interlayer dielectric layer is formed aside he spacers films and on the semiconductor strips. A thermal treatment process is performed on the semiconductor strips, the spacer films and the interlayer dielectric layer. Gate structures are formed between the spacer films.

In accordance with yet another embodiment of the present disclosure, a method of fabricating a semiconductor device includes the following steps. A plurality of semiconductor strips is formed on a substrate, wherein each of the semiconductor strips includes a channel region and source/drain regions. Dummy gate structures are formed on the channel region and spacer films are formed aside the dummy gate structures, wherein the spacer films are doped with a dopant. An interlayer dielectric layer is formed on the semiconductor strips and aside the spacer films, wherein the spacer films comprises a first portion adjacent to sidewalls of the dummy gate structures and a second portion facing away from the sidewalls of the dummy gate structures, and a concentration of the dopant in the first portion varies from a concentration of the dopant in the second portion.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor device, comprising:
patterning a substrate to form a plurality of active regions;
forming isolation features alongside the plurality of active regions;
forming dummy gate structures on the plurality of active regions and spacer films aside the dummy gate structures;
performing a doping process on the spacer films to reduce a coefficient of thermal expansion (CTE) value of the spacer films;
forming an interlayer dielectric layer on the isolation features and aside the spacer films; and
replacing the dummy gate structures with gate structures.

2. The method according to claim 1, wherein the doping process comprises performing ion implantation with at least one ion implant selected from argon (Ar), xenon (Xe), antimony (Sb), indium (In) and arsenic (As).

3. The method according to claim 2, wherein a dose concentration of the ion implant in the ion implantation process is in a range of 2*10¹⁴ atoms/cm² to 10¹⁸ atoms/cm².

4. The method according to claim 2, wherein the doping process comprises performing ion implantation with two ion implants, and wherein a first ion implant is argon (Ar), and a second ion implant is any one of xenon (Xe), antimony (Sb), indium (In) and arsenic (As).

5. The method according to claim 1, wherein the spacer films have tensile stress before performing the doping process, and have compressive stress after performing the doping process.

6. The method according to claim 1, wherein replacing the dummy gate structures with the gate structures comprises:
removing the dummy gate structures located on a portion of the plurality of active regions;
performing a thermal treatment process; and
forming the gate structures on the portion of the plurality of active regions.

7. The method according to claim 1, wherein the spacer films have a first surface facing the dummy gate structures and a second surface facing the interlayer dielectric layer, and wherein a concentration of ions implanted into the spacer films adjacent to the first surface is lower than a concentration of the ions implanted into the spacer films adjacent to the second surface.

8. A method of fabricating a semiconductor device, comprising:
forming a plurality of semiconductor strips on a substrate;
forming spacer films on the plurality of semiconductor strips, and performing a doping process on the spacer films;
forming an interlayer dielectric layer aside the spacers films and on the plurality of semiconductor strips;
performing a thermal treatment process on the plurality of semiconductor strips, the spacer films and the interlayer dielectric layer; and
forming gate structures in between the spacer films.

9. The method according to claim 8, wherein the spacers films have a first coefficient of thermal expansion (CTE) value prior to the doping process, the interlayer dielectric layer has a second CTE value different from the first CTE value, and wherein after performing the doping process on the spacer films, the first CTE value of the spacer films is altered so that a CTE difference between the first CTE value and the second CTE value is reduced.

10. The method according to claim 8, wherein prior to forming the interlayer dielectric layer, the method further comprises:
removing portions of the plurality of semiconductor strips to form a plurality of recessed portions;
forming strained material portions over the plurality of recessed portions; and
forming the interlayer dielectric layer on the strained material portions and aside the spacers films.

11. The method according to claim 8, wherein the spacer films are formed with a first portion contacting the gate structures, and a second portion connected to first portion and sandwiched between the first portion and the interlayer dielectric layer, and wherein a concentration of ions implanted into the second portion of the spacer films is higher than a concentration of ions implanted into the first portion of the spacer films during the doping process.

12. The method according to claim 8, wherein the thermal treatment process is performed at a temperature range of 600° C. to 1300° C.

13. The method according to claim 8, wherein the doping process on the spacer films comprises performing ion implantation with at least one ion implant selected from argon (Ar), xenon (Xe), antimony (Sb), indium (In) and arsenic (As).

14. The method according to claim 8, wherein prior to forming the spacer films on the plurality of semiconductor strips, the method further comprises:
forming isolation features aside the plurality of semiconductor strips;
forming a dielectric layer on the isolation features and over the plurality of semiconductor strips; and
forming the spacer films on the dielectric layer and on the plurality of semiconductor strips, wherein performing the doping process on the spacer films further comprises partially doping the dielectric layer.

15. A method of fabricating a semiconductor device, comprising:
forming a plurality of semiconductor strips on a substrate, wherein each of the plurality of semiconductor strips comprises a channel region and source/drain regions;
forming dummy gate structures on the channel region and spacer films aside the dummy gate structures, wherein the spacer films are doped with a dopant; and
forming an interlayer dielectric layer on the plurality of semiconductor strips and aside the spacer films, wherein the spacer films comprises a first portion adjacent to sidewalls of the dummy gate structures and a second portion facing away from the sidewalls of the dummy gate structures, and a concentration of the dopant in the first portion varies from a concentration of the dopant in the second portion.

16. The method according to claim 15, further comprises:
removing the dummy gate structures on the channel region;
performing a thermal treatment process; and
forming gate structures on the channel region, wherein the gate structures are contacting the first portion of the spacer films.

17. The method according to claim 15, wherein the concentration of the dopant in the first portion is lower than the concentration of the dopant in the second portion.

18. The method according to claim 15, wherein the spacer films are formed of a multilayered structure, wherein the multilayered structure comprises a first layer including the first portion and a second layer including the second portion.

19. The method according to claim 15, wherein prior to forming the interlayer dielectric layer, the method further comprises:
removing portions of the plurality of semiconductor strips in the source/drain regions to form a plurality of recessed portions;
forming strained material portions over the plurality of recessed portions in the source/drain regions; and
forming the interlayer dielectric layer on the strained material portions and aside the spacers films.

20. The method according to claim 15, wherein the dopant is at least one selected from argon (Ar), xenon (Xe), antimony (Sb), indium (In) and arsenic (As).
